(19) United States
(12) Patent Application Publication
(10) Pub. No.: US 2014/0202742 A1
(43) Pub. Date: Jul. 24, 2014

(54) TWO-SIDED LASER PATTERNING ON THIN FILM SUBSTRATES

(71) Applicant: CAMBRIOS TECHNOLOGIES CORPORATION, Sunnyvale, CA (US)

(72) Inventors: David Jones, Mountain View, CA (US); Paul Mansky, San Francisco, CA (US); Michael A. Spaid, Mountain View, CA (US)

(73) Assignee: CAMBRIOS TECHNOLOGIES CORPORATION, Sunnyvale, CA (US)

(21) Appl. No.: 14/161,310

(22) Filed: Jan. 22, 2014

Related U.S. Application Data
(60) Provisional application No. 61/755,343, filed on Jan. 22, 2013.

(51) Int. Cl. H05K 1/02; H05K 3/02

(52) U.S. Cl. CPC H05K 1/0274; H05K 3/027
USPC 174/253; 219/121.69

(57) ABSTRACT

Disclosed herein are double-sided transparent conductive films suitable for patterning by laser ablation.

### BACKGROUND

1. Technical Field

This invention is related to transparent conductors, methods of patterning the same, and applications thereof.

2. Description of the Related Art

Transparent conductors refer to thin conductive films coated on high-transmittance surfaces or substrates. Transparent conductors may be manufactured to have surface conductivity while maintaining reasonable optical transparency. Such surface conducting transparent conductors are widely used as transparent electrodes in flat liquid crystal displays, touch panels, electroluminescent devices, and thin film photovoltaic cells; as anti-static layers; and as electromagnetic wave shielding layers.

Currently, vacuum deposited metal oxides, such as indium tin oxide (ITO), are the industry standard materials for providing optical transparency and electrical conductivity to dielectric surfaces such as glass and polymeric films. However, metal oxide films are fragile and prone to damage during bending or other physical stresses. They also require elevated deposition temperatures and/or high annealing temperatures to achieve high conductivity levels. Moreover, the process of vacuum deposition is not conducive to forming patterns and circuits. This typically results in the need for costly patterning processes such as photolithography. In addition, a metal oxide film tends to have trouble properly adhering to certain substrates that are prone to adsorbing moisture, such as plastic and organic substrates (e.g., polycarbonates). Applications of metal oxide films on these flexible substrates are therefore severely limited.

In recent years there is a trend to replace current industry standard transparent conductive ITO films in flat panel displays with a composite material of interconnecting metal nanostructures (e.g., silver nanowires) embedded in a matrix, the matrix being insulating or conductive. Typically, a transparent conductive film is formed by first coating on a substrate a coating solution including metal nanowires, an optional binder and a volatile liquid carrier. The optional binder provides the matrix upon removal of the volatile components of the ink composition. Irrespective of the presence of a binder, an overcoat layer may be further coated after the deposition of the nanostructures. The overcoat layer typically comprises one or more polymeric or resin materials. The resulting transparent conductive film has a sheet resistance comparable or superior to that of the ITO films.

Nanostructure-based coating technologies are particularly suited for producing robust electronics on large-area, flexible substrates. See U.S. Pat. Nos. 8,049,333; 8,094,247; 8,018,568; 8,174,667; and 8,018,563 in the name of Cambrios Technologies Corporation, which are hereby incorporated by reference in their entirety. The solution-based format for forming nanostructure-based thin film is also compatible with existing coating and lamination techniques. Thus, additional thin films of overcoat, undercoat, adhesive layer, and/or protective layer can be integrated into a high through-put process for forming optical stacks that include nanostructure-based transparent conductors.

There remains a need in the art to pattern transparent conductors in a low-cost, high-throughput process.

### BRIEF SUMMARY

Described herein are transparent conductors and methods of patterning the same.

One embodiment provides a double-sided transparent conductive film comprising: a beam-blocking substrate having a first surface and a second surface opposite to the first surface; a first conductive layer disposed on the first surface, the first conductive layer comprising a first plurality of conductive nanostructures; a second conductive layer disposed on the second surface, the second conductive layer comprising a second plurality of conductive nanostructures, wherein the beam-blocking substrate is capable of blocking a laser beam having wavelengths in the range of 180 nm-1 mm.

In various embodiments, the beam-blocking substrate is a UV-blocking substrate (blocking wavelengths in the 180-400 nm range) or an IR-blocking substrate (blocking wavelengths in the 700-1 mm range), depending on the types of laser used for patterning.

Another embodiment provides a double-sided transparent conductive film comprises: a first substrate; a first conductive layer disposed on the first substrate, the first conductive layer comprising a first plurality of conductive nanostructures; a second substrate; a second conductive layer disposed on the second substrate, the second conductive layer comprising a second plurality of conductive nanostructures; and a beam-blocking adhesive layer disposed between the first substrate and the second substrate, the beam-blocking adhesive layer and the first conductive layer being on opposite sides of the first substrate, and the beam-blocking adhesive layer and the second conductive layer being on opposite sides of the second substrate, wherein the beam-blocking adhesive layer is capable of blocking a laser beam having wavelengths in the range of 180 nm-1 mm.

In various embodiments, the beam-blocking adhesive layer is a UV-blocking adhesive layer (blocking wavelengths in the 180-400 nm range) or an IR-blocking adhesive layer (blocking wavelengths in the 700-1 mm range), depending on the types of laser used for patterning.

A further embodiment provides a method for double-sided patterning comprising:

providing a double-sided transparent conductive film having at least one beam-blocking layer disposed between a first conductive layer and a second conductive layer;

laser patterning the first conductive layer with a first laser beam; and

laser patterning the second conductive layer with a second laser beam, wherein laser patterning comprises directing the first laser beam to predetermined regions of the first conductive layer, and the second laser beam to predetermined regions of the second conductive layer, thereby independently creating insulating regions in the first and second conductive layers.

### BRIEF DESCRIPTION OF THE SEVERAL VIEWS OF THE DRAWINGS

In the drawings, identical reference numbers identify similar elements. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn are not intended to convey any information regarding the actual shape of the particular elements, and they have been solely selected for ease of recognition in the drawings.

FIG. 1 illustrates one embodiment in which a double-sided transparent conductive film comprises a beam-blocking substrate.

FIG. 2 shows the absorption spectra of two beam-blocking substrates.

FIG. 3 illustrates one embodiment in which a double-sided transparent conductor comprises additional beam-blocking coatings.

FIG. 4 illustrates a further embodiment in which a double-sided transparent conductor comprises a beam-blocking adhesive layer.

FIG. 5 illustrates another embodiment in which a double-sided transparent conductor comprises additional beam-blocking coatings.

### DETAILED DESCRIPTION

Described herein are transparent conductors and methods of patterning the same. The patterned transparent conductors are particularly suitable as transparent electrodes in a wide variety of devices including, without limitation, display devices (e.g., touch screens, liquid crystal displays, plasma display panels and the like), electroluminescent devices such as OLED devices, and photovoltaic cells.

As used herein, “patterning” broadly refers to a process that creates conductive features (e.g., lines or traces) demarcated by electrically insulating regions on the surface of a substrate. A pattern does not necessarily have repeating or regular features; rather, a pattern can simply be an arrangement in which any one conductive feature (e.g., conductive line) is electrically isolated from another conductive feature by one or more insulating regions.

Nevertheless, many applications of the patterned transparent conductors require regularly spaced conductive lines of substantially the same width. For instance, regularly patterned conductive films are integral parts of a touch panel. A touch panel is an interactive input device integrated onto an electronic display, which allows a user to input instructions by touching the screen. Two opposing, patterned transparent conductive films are used to detect the coordinate of the location of the touch input. When the touch panel is touched, a small change in the electrical voltage at the location of the touch input is detected.

Generally speaking, a transparent conductive thin film or network of randomly distributed and interconnecting conductive nanostructures is first prepared by coating a coating solution on a substrate. The thin film may be patterned by removing conductive nanostructures in predetermined regions to create the insulating regions. The remaining conductive nanostructures are therefore arranged in a predetermined pattern.

It is particularly desirable for certain applications (e.g., touch screens) that the pattern has low-visibility or invisible, i.e., the conductive features and the insulating regions have substantially the same visual appearance. Thus, as an alternative to removing the conductive nanostructures to create the insulating regions, patterning may be achieved by rendering the conductive nanostructures non-conductive in regions that will become insulating. More specifically, a patterning step may create insulating regions in which the nanostructures have structural defects such as nicks and breakage and can no longer form a conductive network. However, the presence of the residual nanostructures (though incapable of forming conductive pathways) gives a visual appearance similar to that of the conductive features. See U.S. Pat. No. 8,018,568, supra.

Chemical etching and subsequent washing are effective to completely or partially remove the nanostructures to create insulating regions. See U.S. Pat. No. 8,094,247, supra.

Contrasting to a wet etching process involving chemicals, laser ablation is a dry etch process. Laser ablation uses laser pulses, e.g., radiations in the ultraviolet (UV), visible (VIS), or infrared (IR) ranges, to directly create patterns without using masks or chemicals. Laser ablation has been shown to be effective in creating isolated, low-visibility conductive patterns in silver nanowire-based transparent conductors. See “Laser Patterning of Silver Nanowire”, T. Pothoven, Information Display, 9 (12), 20-24, (2012), which is hereby incorporated by reference herein in its entirety. The silver nanowires in regions that absorb the laser pulses become partially or fully vaporized or otherwise structurally compromised by heat, thereby leading to a loss in conductivity.

Table 1 shows a number of lasers and their corresponding wavelengths ranging from UV (the shortest) to IR (the longest).

TABLE 1

| LASER TYPE | WAVELENGTH (Nanometers) |
|---|---|
| Argon Fluoride | 190 |
| Xenon Chloride | 308 and 459 |
| Xenon Fluoride | 353 and 459 |
| Helium Cadmium | 325-442 |
| Rhodamine 6G | 450-650 |
| Copper Vapor | 511 and 578 |
| Argon | 457-528 (514.5 and |
| | 488 most used) |
| Frequency doubled Nd: YAG | 532 |
| Helium Neon | 543, 594, 612, and 632.8 |
| Krypton | 337.5-799.3 (647.1-676.4 |
| | most used) |
| Ruby | 694.3 |
| Laser Diodes | 630-950 |
| Ti: Sapphire | 690-960 |
| Alexandrite | 720-780 |
| Nd: YAG | 1064 |
| Hydgrogen Fluoride | 2600-3000 |
| Erbium: Glass | 1540 |
| Carbon Monoxide | 5000-6000 |
| Carbon Dioxide | 10600 |

For certain transparent conductor configurations, laser ablation may encounter production limitations. For instance, in the production of touch panels, two patterned, electrically conductive layers can be formed on two substrates with a spacer mechanism located between the two substrates. It is also possible to form each conductive layer on either side of a single substrate, so that the single substrate both supports the conductive layers and acts as a spacer layer. As used herein, a double-sided transparent conductive layer includes a first transparent conductive layer, a second transparent conductive layer, and at least one transparent substrate disposed therebetween. Because the substrate is necessarily transparent, laser radiation used for patterning a first conductive layer on one side of the substrate may pass through the substrate and impact the conductivity of a second conductive layer on the opposite side of the substrate.

Thus, described herein are two transparent conductive layers in a double-sided thin film construction, in which the two transparent conductive layers can be independently patterned by laser ablation. In particular, the patterns are created without crosstalk. In other words, patterning one conductive layer does not have any effect on patterning the other conductive layer, which is on the opposite side of a transparent substrate. The double-sided structure and the method of patterning the same are particularly suited for patterning transparent electrodes for a touch screen.

In particular, it is employed herein a laser beam-blocking layer disposed between two transparent conductive layer. The laser beam-blocking layer acts as a barrier layer to block or attenuate a laser beam that patterns one transparent conductive layer from reaching the other transparent conductive layer in energy that might be sufficient to cause structural damage.

The laser beam-blocking layer, also referred to as “beam-blocking layer,” comprises substances that block or absorb the specific wavelengths of the laser beam while substantially transmitting light in all of the visible range (400-700 nm). For practical purposes, beam-blocking layer may preferably be a UV-blocking layer or IR-blocking layer, for use with UV laser (180-400 nm) and IR laser (700 nm-1 mm), respectively.

It should be understood that, while a beam-blocking layer may be capable of blocking a range of wavelengths at various efficiencies, the ones that matter are the wavelengths used for laser ablation, which are generally very narrow energy bands characteristic of laser beams.

Patterning of a conductive layer creates regions or lines of relatively low or no conductivity between conductive regions to electrically isolate such conductive regions from each other. Patterning a double-sided transparent conductive layer by laser ablation achieves the following three objectives: (1) electrically patterning the first conductive layer on which the laser beam is incident using a first laser; (2) avoiding simultaneously electrically patterning the second conductive layer on the opposite surface of the substrate with the beam from the first laser that is patterning the first conductive layer; and (3) minimizing any damage to the substrate from the energy absorption process.

The incorporation of a beam-blocking layer must allow for a simultaneous achievement of objectives (2) and (3), which are to some extent in opposition. If insufficient energy is allowed to pass through the substrate and subsequently absorbed by the second conductive layer on the opposite side of the substrate, the second conductive layer will become electrically isolated with the same pattern as the first conductive layer. On the other hand, if too much energy is absorbed by the substrate, the substrate may become damaged. In particular, if essentially all of the energy is absorbed, this also implies that the majority of the energy is absorbed in a thin layer near the surface of incidence (by Beer's law).

These competing requirements can best be balanced by (1) operating the laser close to the ablation threshold for the first conductive layer, for example, at a power level 10-20% above the ablation threshold; and (2) distributing the beam absorbing agents uniformly throughout the substrate in a sufficient amount such that the laser power is reduced to 10-20% below the ablation threshold when it reaches the opposite surface of the substrate. In this way, the goal of avoiding crosstalk is achieved with the substrate only having to absorb a relatively small fraction of the incident power (on the order of 20-40%). Furthermore, by Beer's law, the energy is absorbed continuously throughout the substrate film, but most strongly absorbed near the incident surface. By choosing the thickness and optical density of the substrate such that only 20-40% of the total beam energy is absorbed, the absorption is taking place relatively uniformly throughout the thickness of the substrate. In contrast, if nearly 100% of the beam is absorbed, it follows that not only is more total power absorbed, but the absorption (energy per unit volume) will also be much more concentrated and higher near the surface of incidence.

Thus, in some embodiments, 100% of the laser beam may be effectively blocked by the beam-blocking layer. In certain embodiments, however, it may be advantageous to block only a portion of the laser beam as too much energy absorbed may damage the beam-blocking layer. On the other hand, care should be taken to ensure that sufficient energy is blocked or attenuated so any energy that could reach the other transparent conductive film is insufficient to cause any structural damage (e.g., at least 10-20% below the ablation threshold). In various embodiments, the beam-blocking layer should block at least 10%-20% of the beam used for laser ablation, to avoid crosstalk. In other embodiment, the beam-blocking layer should block not more than 20%-50%, 30%-50% or 40%-50% of the beam used for laser ablation, to minimize the potential for damage to the substrate.

The thickness of the beam-blocking layer plays a role in beam-blocking efficiency. For a given concentration of beam-blocking agents, the thicker the beam-blocking layer, the more capacity the beam-blocking layer has. For a given amount of total energy absorption (e.g. 50% blocking), the energy absorption per unit volume will be lower if the substrate is thicker and the concentration of absorbing species and optical absorbance are correspondingly lower.

In various embodiments, the beam-blocking layer may be a barrier layer specifically designed for blocking the laser beam. In other embodiments, the beam-blocking layer may serve dual functions of being a barrier layer as well as a substrate that supports the transparent conductive film. The location of the beam-blocking layer in a double-sided transparent thin film construction is not particularly limited so long as it is disposed between the first and second transparent conductive films.

The beam-blocking layer may be a single layer or a multi-layer construction. In a multi-layer construction, it is not necessary that every layer in the multi-layer construction has beam-blocking properties. Rather, the beam-blocking layer is evaluated for its beam-blocking capacity as a whole. In a multi-layer construction, the layers may be bonded together by an optically clear adhesive, which may be beam-blocking itself.

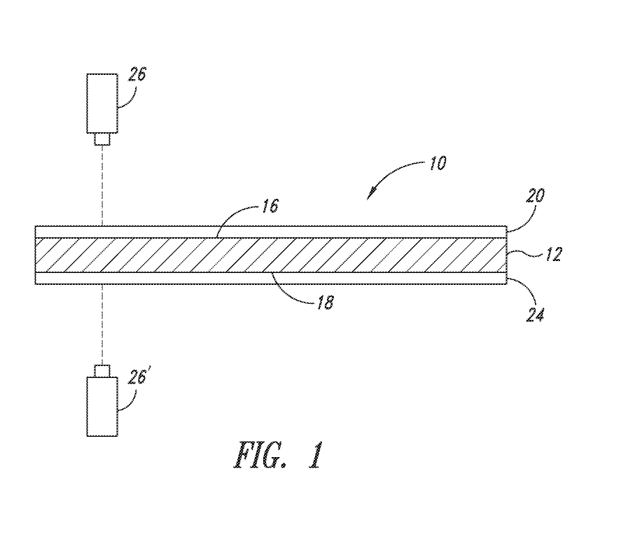

As shown in FIG. 1, one embodiment provides a double-sided transparent conductive film (10) comprising a beam-blocking layer, e.g., a UV-blocking or IR-blocking substrate (12) having a first surface (16) and a second surface (18) opposite to the first surface (16); a first conductive layer (20) disposed on the first surface (16), the first conductive layer comprising a first plurality of conductive nanostructures (not shown); a second conductive layer (24) disposed on the second surface (18), the second conductive layer comprising a second plurality of conductive nanostructures (not shown).

Also shown in FIG. 1, two laser beam sources (26) and (26′) are disposed on either sides of the transparent film (10). They preferably emit in the UV range or IR range and are therefore capable of independently and simultaneously creating patterns on the first conductive layer (20) and the second conductive layer (24) without crosstalk. Thus, a further embodiment provides a method for double-sided patterning comprising: providing a double-sided transparent conductive film (10); laser patterning the first conductive layer (20) with a first laser beam (26); and laser patterning the second conductive layer (24) with a second laser beam (26′), wherein directing the first laser beam to predetermined regions of the first conductive layer, and the second laser beam to predetermined regions of the second conductive layer, thereby independently creating insulating regions in the first and second conductive layers.

The patterning of the conductive layers (20) and (24) may be carried out simultaneously or serially. If used serially, laser beams (26) and (26′) can be the same laser. Advantageously, the presence of the beam-blocking substrate (12) attenuates the first laser beam (26) after ablating the first conductive layer (20). Because the first laser beam (26) is prevented from reaching the second conductive layer (24) at a sufficient enough energy to ablate (i.e., below the ablation threshold), undesired ablation of conductive layer (24) by laser beam (26) is avoided. Likewise, the beam-blocking substrate (12) has the same effect in preventing the second laser beam (26′) from reaching the first conductive layer (20) with sufficient energy to ablate (i.e., below the ablation threshold).

In one specific embodiment, the beam-blocking layer is a UV-blocking layer and the double-sided transparent conductive film is to be patterned by laser ablation by UV light. The UV-blocking substrate is capable of absorbing a portion of the UV light at the wavelength used to pattern the conductive film (e.g., at least 20%) but substantially transmitting all wavelengths of visible light (>85%).

Typically, a UV-blocking layer is formed of a polymeric or resinous material comprising one or more UV-absorbing agents. The UV-absorbing agent may be chemically or covalently attached to the molecular frames of the polymer. Alternatively, the UV-absorbing agent may be blended with or coated on the polymeric layer. The UV-blocking substrate is preferably from 20 to 250 μm thick.

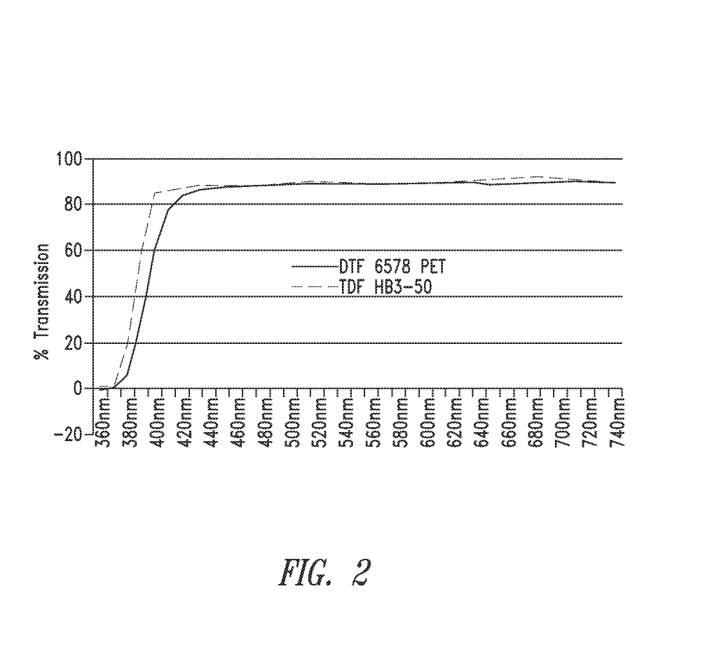

An exemplary UV-absorbing substrate is a 50 μm thick polyethylene terephthalate (PET) film from Teijin DuPont Films under the designation “HB3-50.” Another exemplary UV-absorbing substrate is a 125 μm thick PET film from DuPont Teijin under the designation XST6758. Transmission spectra for these two types of PET film are shown in FIG. 2, and were obtained using a Konica Minolta CM5 spectrophotometer.

UV-absorbing substrates are typically formulated for the purpose of protecting themselves or other materials from damage by solar UV radiation, which is typically defined to consist of wavelengths below about 400 nm. Blocking wavelengths longer than 400 nm causes a yellow appearance of the material. Thus, for protective purposes, most UV-absorbing films have very high transmission above about 400 nm, and a sharp cutoff to near zero transmission just below 400 nm (i.e., near 100% UV attenuation).

However, for the present disclosure, it may be desirable to use substrates with a much lower degree of UV absorption (i.e., less sharp cutoff in the UV region). For example, if a 365 nm laser is used for patterning, then it may be desirable for the total UV attenuation at 365 nm to be on the order of 20%-50% (as opposed to near 100%). Thus, in various embodiments, the UV-blocking layer used herein contain a much lower concentration of UV absorbing agents than a typical or commercial UV absorbing PET.

A UV-absorbing substrate can also be produced by laminating two non-UV absorbing films together using a UV-absorbing optically clear adhesive (OCA), such as 8172PCL by 3M™. The UV-absorbing agents and substrates are described in further detail below.

The first and second conductive layers may be coated on the UV-blocking substrate through a solution-based approach, as described in U.S. Published Application No. 2011/0174190, in the name of Cambrios Technologies Corporation, which is hereby incorporated by reference in its entirety. Alternatively, the first and second conductive layers may be laminated on the UV-blocking substrate through a film-transfer approach, as described in U.S. Published Application 2013/0105770, in the name of Cambrios Technologies Corporation, which is hereby incorporated by reference in its entirety.

In another specific embodiment, the beam-blocking substrate (12) is an IR-blocking layer for use with an infrared (IR) laser, as an alternative to the UV lasers described above. The IR-blocking layer should absorb the wavelength of the IR light used for laser ablation. The IR-blocking layer comprises one or more IR-blocking or IR-absorbing agents. Examples of IR-blocking or IR-absorbing agents include, for example, IR dyes, which are discussed in further detail herein.

As in the UV-blocking layer, it may be advantageous for the IR-blocking layer to absorb only a fraction of the laser beam to avoid damaging the IR-blocking layer while ensure sufficient blocking capacity. In certain embodiments, the IR-blocking layer absorbs at least 10%, 20% or 25%, or 20-50% of the IR laser beam.

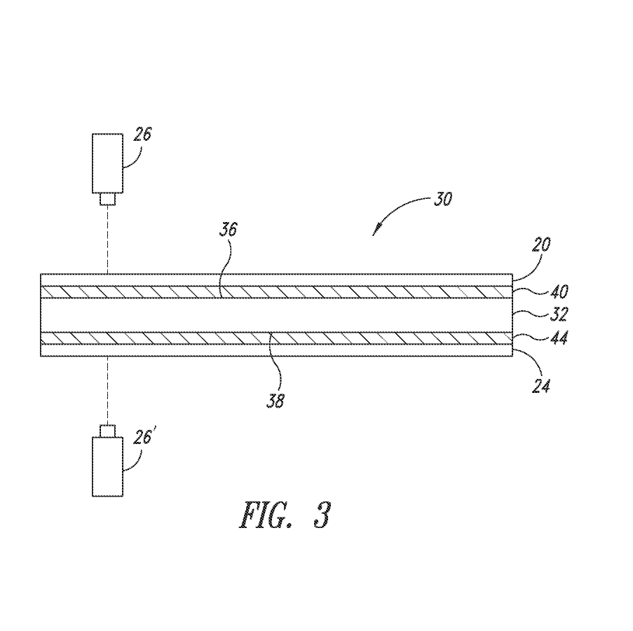

FIG. 3 shows a further embodiment in which beam-blocking coatings provide laser attenuation. More specifically, a double-sided transparent conductive film (30) comprises a substrate (32) having a first surface (36) and a second surface (38) opposite to the first surface (36); a first beam-blocking coating (40) disposed on the first surface (36), a first conductive layer (20) disposed on first beam-blocking coating (40), the first conductive layer (20) comprising a first plurality of conductive nanostructures (not shown); a second beam-blocking coating (44) disposed on the second surface (38); and a second conductive layer (24) disposed on the second beam-blocking coating (the first conductive layer comprising a second plurality of conductive nanostructures (not shown). The beam-blocking coatings (40) and (44) provide laser attenuation during patterning. The substrate (32) may itself be beam-blocking, similar to the beam-blocking substrate (12) of FIG. 1.

The beam-blocking coating is a thin film of one or more beam-blocking agent, as defined herein. Thus, like beam-blocking substrates, the beam-blocking coating is transparent to visible light and absorbs UV light or IR light. The beam-blocking agent may be formulated into a coating solution and coated on the substrate.

The double-sided transparent conductive films of FIGS. 1 and 3 may further comprise overcoats or other protecting layers.

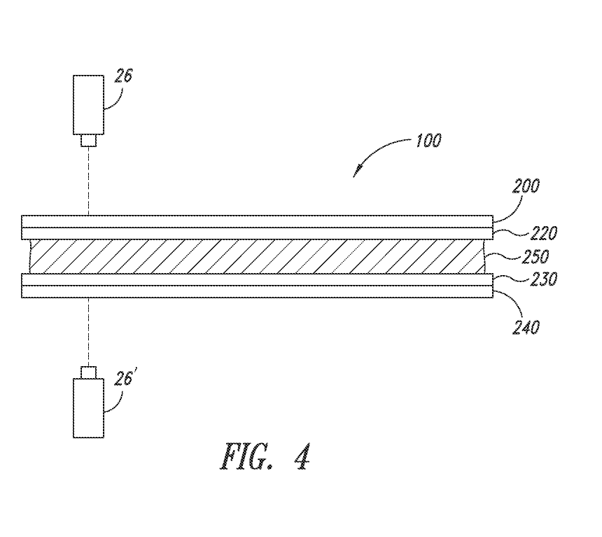

FIG. 4 illustrates another embodiment. In FIG. 4, a double-sided transparent conductive film (100) comprises:

a first substrate (220);

a first conductive layer (200) disposed on the first substrate, the first conductive layer comprising a first plurality of conductive nanostructures;

a second substrate (230);

a second conductive layer (240) disposed on the second substrate (230), the second conductive layer comprising a second plurality of conductive nanostructures; and

a beam-blocking adhesive layer (250) disposed between the first substrate (220) and the second substrate (230), the beam-blocking adhesive layer (250) and the first conductive layer (200) being on opposite sides of the first substrate (220), and the beam-blocking adhesive layer (250) and the second conductive layer (240) being on opposite sides of the second substrate (230).

In one embodiment, the beam-blocking adhesive layer (250) is transparent in the visible light range but absorbs UV light. An example of a suitable UV-blocking adhesive is manufactured by 3M Corporation under the designation “8172PCL.” The UV-blocking adhesive (250) is preferably from 25 to 50 μm thick, but could be greater or less than the preferred range. In this embodiment, the UV-blocking adhesive (250) attenuates the laser beam from laser source (26) after the laser beam ablates conductive layer (200) but before reaching layer 240, thereby avoiding undesired ablation of conductive layer (240). Similarly, the beam-blocking adhesive 250 attenuates the beam from laser source (26′) after the beam ablates conductive layer (240) but before reaching conductive layer (200) with sufficient energy to ablate the second conductive layer (200), thereby avoiding undesired ablation of conductive layer (200).

In another embodiment, the beam-blocking adhesive layer (250) is an IR-blocking layer and the double-sided transparent conductive film is to be patterned by laser ablation by IR beam. The IR-blocking layer comprises one or more IR-blocking or IR-absorbing agents. Examples of IR-blocking or IR-absorbing agents include, for example, IR dyes, which are discussed in further detail herein.

Substrates (220) and (230) are transparent to visible light. They may also be UV or IR beam-blocking substrates themselves, if additional or enhanced attenuation is desired.

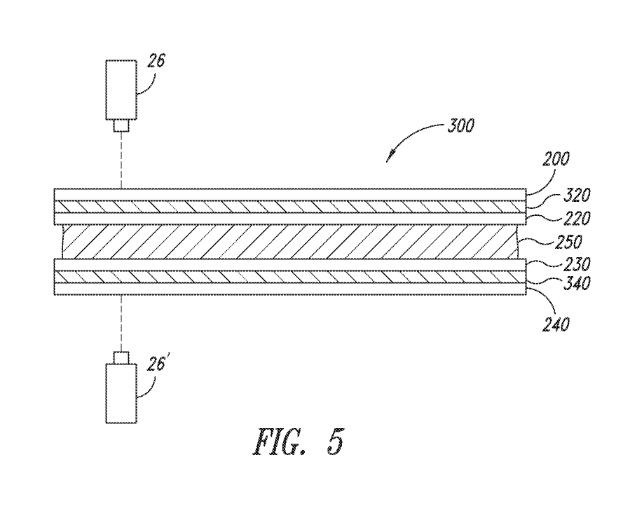

Additional beam-blocking coatings may be further included to enhance the laser attenuation. FIG. 5 shows a double-sided transparent conductive film (300), which otherwise resembles the double sided film of FIG. 4, further comprising a first beam-blocking coating (320) interposed between the first conductive layer (200) and the first substrate (220); and a second beam-blocking coating (340) interposed between the second conductive layer (240) and the second substrate (230).

It should be noted that the beam-blocking layer of any one of the configuration shown in FIGS. 1, 3, 4 and 5 may be a UV-blocking layer or an IR-blocking layer, depending on the types of the laser used for patterning.

The various constituents of the claimed transparent conductive films are described in further detail below.

### UV-Blocking Agents

UV-blocking agents, also referred to as “UV-absorbing agents,” are chemical compounds or moieties that are capable of absorbing UV-light. They may be organic or inorganic substances. Organic UV-absorbing agents may be salicylate-based, benzophenone-based, benzotriazole-based, triazine-based, benzotriazine-based, substituted acrylonitrile-based.

Specific examples of UV-blocking agents include, without limitation, 2-(2-hydroxyphenyl)-benzotriazole (BTZ), 2-hydroxyphenyl-s-triazine, or 2-hydroxy-benzophenones.

Commercial sources for UV-absorbing agents include benzothiazole-based and triazine-based agents sold under the trade name of Tinuvin® (by BASF), or benzophenone-based agent under the trade name of Chimassor® (by BASF).

The UV-blocking agent may be physically combined with a resin to formulate into a coating solution, which may be coated on a surface to provide a UV-blocking coating or adhesive layer.

The UV-blocking agent may also be chemically or covalently combined with polymer through addition-polymerizing, i.e., by reacting with a double bond-containing group such as a vinyl group, an acryloyl group or a methacryloyl group, or an alcoholic hydroxyl group, an amino group, a carboxyl group, an epoxy group, an isocyanate group or the like. Alternatively, the UV-blocking agent may be copolymerized or grafted onto a thermoplastic resin such as an acrylic resin. The UV-blocking agent may also be dispersed in a resin layer.

In various embodiments, two or more UV-blocking agents may be combined in order to provide attenuations for a broader range of laser beams.

### IR-Blocking Agent

IR-blocking agents are capable of absorbing in the IR region, and may be selected from a wide range of IR dyes. IR dyes are typically complex organic compounds having aromatic ring structures and/or metallic components. Many IR dyes are available from commercial venders (e.g., Sigma-Aldrich).

Depending on the wavelength of the laser used for the laser ablation, suitable IR dyes may be selected based on their absorptions in the IR regions (λₘₐₓ). Exemplary IR dyes are as follows: 1,1′,3,3,3′,3′-Hexamethylindotricarbocyanine iodide (740 nm), 1,1′-Diethyl-4,4′-dicarbocyanine iodide (814 nm), 1,4,8,11,15,18,22,25-Octabutoxy-29H,31H-phthalocyanine (762 nm), 2,11,20,29-Tetra-tert-butyl-2,3-naphthalocyanine (784 nm), 2,3-Naphthalocyanine (712 nm), 3,3′-Diethylthiatricarbocyanine iodide (765 nm), 5,9,14,18,23,27,32,36-Octabutoxy-2,3-naphthalocyanine (867 nm), aluminum 1,8,15,22-tetrakis(phenylthio)-29H,31H-phthalocyanine chloride (759 nm), Aluminum 2,9,16,23-tetrakis(phenylthio)-29H,31H-phthalocyanine chloride (725 nm), cobalt(II) 2,3-naphthalocyanine (731 nm), copper(II) 1,4,8,11,15,18,22,25-octabutoxy-29H,31H-phthalocyanine (740 nm), copper(II) 5,9,14,18,23,27,32,36-octabutoxy-2,3-naphthalocyanine (853 nm), manganese(II) phthalocyanine (727 nm), manganese(III) phthalocyanine chloride (726 nm), nickel(II) 1,4,8,11,15,18,22,25-octabutoxy-29H,31H-phthalocyanine (743 nm), Nickel(II) 5,9,14,18,23,27,32,36-octabutoxy-2,3-naphthalocyanine (848 nm).

IR-absorbing agents in the longer IR range include, for example, those available from Sigma-Aldrich in the names of IR-1061 dye, IR-1051 dye, IR-1050 dye, IR-1048 dye, in which the numerical suffix denotes the maximum absorption wavelength. A commonly used IR wavelength for laser ablation is 1064 nm. Thus, IR dyes that absorb in and around this wavelength is a suitable IR-absorbing agent.

### Conductive Nanostructures

As used herein, “conductive nanostructures” generally refer to electrically conductive nano-sized structures, at least one dimension of which (i.e., width or diameter) is less than 500 nm; more typically, less than 100 nm or 50 nm. In various embodiments, the width or diameter of the nanostructures are in the range of 10 to 40 nm, 20 to 40 nm, 5 to 20 nm, 10 to 30 nm, 40 to 60 nm, 50 to 70 nm.

One way for defining the geometry of a given nanostructure is by its “aspect ratio,” which refers to the ratio of the length and the width (or diameter) of the nanostructure. In preferred embodiments, the nanostructures are anisotropically shaped (i.e. aspect ratio≠1). The anisotropic nanostructure typically has a longitudinal axis along its length. Exemplary anisotropic nanostructures include nanowires (solid nanostructures having aspect ratio of at least 10, and more typically, at least 50), nanorod (solid nanostructures having aspect ratio of less than 10) and nanotubes (hollow nanostructures).

Lengthwise, anisotropic nanostructures (e.g., nanowires) are more than 500 nm, or more than 1 μm, or more than 10 μm in length. In various embodiments, the lengths of the nanostructures are in the range of 5 to 30 μm, or in the range of 15 to 50 μm, 25 to 75 μm, 30 to 60 μm, 40 to 80 μm, or 50 to 100 μm.

Conductive nanostructures are typically of a metallic material, including elemental metal (e.g., transition metals) or a metal compound (e.g., metal oxide). The metallic material can also be a bimetallic material or a metal alloy, which comprises two or more types of metal. Suitable metals include, but are not limited to, silver, gold, copper, nickel, gold-plated silver, platinum and palladium. It should be noted that although the present disclosure describes primarily nanowires (e.g., silver nanowires), any nanostructures within the above definition can be equally employed.

Typically, conductive nanostructures are metal nanowires that have aspect ratios in the range of 10 to 100,000. Larger aspect ratios can be favored for obtaining a transparent conductor layer since they may enable more efficient conductive networks to be formed while permitting lower overall density of wires for a high transparency. In other words, when conductive nanowires with high aspect ratios are used, the density of the nanowires that achieves a conductive network can be low enough that the conductive network is substantially transparent.

Metal nanowires can be prepared by known methods in the art. In particular, silver nanowires can be synthesized through solution-phase reduction of a silver salt (e.g., silver nitrate) in the presence of a polyol (e.g., ethylene glycol) and poly(vinyl pyrrolidone). Large-scale production of silver nanowires of uniform size can be prepared and purified according to the methods described in U.S. Published Application Nos. 2008/0210052, 2011/0024159, 2011/0045272, and 2011/0048170, all in the name of Cambrios Technologies Corporation, the assignee of the present disclosure.

### Nanostructure Conductive Layer

A “nanostructure conductive layer” or “conductive layer” is a conductive network of interconnecting conductive nanostructures (e.g., metal nanowires) that provide the electrically conductive media of a transparent conductor. Since electrical conductivity is achieved by electrical charge percolating from one metal nanostructure to another, sufficient metal nanowires must be present in the conductive network to reach an electrical percolation threshold and become conductive. The surface conductivity of the nanostructure conductive layer is inversely proportional to its surface resistivity, sometimes referred to as sheet resistance, which can be measured by known methods in the art. As used herein, “electrically conductive” or simply “conductive” corresponds to a surface resistivity of no more than 10⁴Ω/□, or more typically, no more than 1,000Ω/□, or more typically no more than 500Ω/□, or more typically no more than 200Ω/□. The surface resistivity depends on factors such as the aspect ratio, the degree of alignment, degree of agglomeration and the resistivity of the interconnecting conductive nanostructures.

In certain embodiments, the conductive nanostructures may form a conductive network on a substrate without a binder. In other embodiments, a binder may be present that facilitates adhesion of the nanostructures to the substrate. Suitable binders include optically clear polymers including, without limitation: polyacrylics such as polymethacrylates (e.g., poly(methyl methacrylate)), polyacrylates and polyacrylonitriles, polyvinyl alcohols, polyesters (e.g., polyethylene terephthalate (PET), polyester naphthalate, and polycarbonates), polymers with a high degree of aromaticity such as phenolics or cresol-formaldehyde (Novolacs®), polystyrenes, polyvinyltoluene, polyvinylxylene, polyimides, polyamides, polyamideimides, polyetherimides, polysulfides, polysulfones, polyphenylenes, and polyphenyl ethers, polyurethane (PU), epoxy, polyolefins (e.g. polypropylene, polymethylpentene, and cyclic olefins), acrylonitrile-butadiene-styrene copolymer (ABS), cellulosics, silicones and other silicon-containing polymers (e.g. polysilsesquioxanes and polysilanes), polyvinylchloride (PVC), polyacetates, polynorbornenes, synthetic rubbers (e.g., EPR, SBR, EPDM), and fluoropolymers (e.g., polyvinylidene fluoride, polytetrafluoroethylene (TFE) or polyhexafluoropropylene), copolymers of fluoro-olefin and hydrocarbon olefin (e.g., Lumiflon®), and amorphous fluorocarbon polymers or copolymers (e.g., CYTOP® by Asahi Glass Co., or Teflon® AF by Du Pont). Additional suitable binders include carboxy methyl cellulose (CMC), 2-hydroxy ethyl cellulose (HEC), hydroxy propyl methyl cellulose (HPMC), methyl cellulose (MC), poly vinyl alcohol (PVA), tripropylene glycol (TPG), and xanthan gum (XG).

Typically, the optical transparence or clarity of the transparent conductor (i.e., a conductive network on a non-conductive substrate) can be quantitatively defined by parameters including light transmission and haze. “Light transmission” (or “light transmissivity”) refers to the percentage of an incident light transmitted through a medium. In various embodiments, the light transmission of the conductive layer is at least 80% and can be as high as 98%. Performance-enhancing layers, such as an adhesive layer, anti-reflective layer, or anti-glare layer, may further contribute to reducing the overall light transmission of the transparent conductor. In various embodiments, the light transmission (T %) of the transparent conductors can be at least 50%, at least 60%, at least 70%, or at least 80% and may be as high as at least 91% to 92%, or at least 95%.

Haze (H %) is a measure of light scattering. It refers to the percentage of the quantity of light separated from the incident light and scattered during transmission. Unlike light transmission, which is largely a property of the medium, haze is often a production concern and is typically caused by surface roughness and embedded particles or compositional heterogeneities in the medium. Typically, haze of a conductive film can be significantly impacted by the diameters of the nanostructures. Nanostructures of larger diameters (e.g., thicker nanowires) are typically associated with a higher haze. In various embodiments, the haze of the transparent conductor is no more than 10%, no more than 8%, or no more than 5% and may be as low as no more than 2%, no more than 1%, or no more than 0.5%, or no more than 0.25%.

### Substrate

Substrate refers to a non-conductive material onto which the metal nanostructure is coated or laminated. The substrate can be rigid or flexible. The substrate can be clear or opaque. Suitable rigid substrates include, for example, glass, polycarbonates, acrylics, and the like. Suitable flexible substrates include, but are not limited to: polyesters (e.g., polyethylene terephthalate (PET), polyester naphthalate, and polycarbonate), polyolefins (e.g., linear, branched, and cyclic polyolefins), polyvinyls (e.g., polyvinyl chloride, polyvinylidene chloride, polyvinyl acetals, polystyrene, polyacrylates, and the like), cellulose ester bases (e.g., cellulose triacetate, cellulose acetate), polysulphones such as polyethersulphone, polyimides, silicones and other conventional polymeric films. Additional examples of suitable substrates can be found in, e.g., U.S. Pat. No. 6,975,067.

Unless otherwise specified, a substrate is substantially transparent (>85% transmission) in the visible light range, i.e., 390 nm-900 nm. A UV-blocking substrate may further comprise UV-blocking agent embedded in the thickness of the substrate or coated on the surfaces of the substrate. The UV-blocking substrate transmits visible light and absorbs some portion of light having wavelengths in the range of 10 nm-390 nm, and more specifically, absorbs light at the wavelength of the beam used to pattern the conductive coating. Similarly, an IR-blocking substrate transmits visible light and absorbs some portion of light having wavelengths in the range of 700 nm-1 mm, and more specifically, absorbs light at the wavelength of the IR beam used to pattern the conductive film.

The substrate may be in a single layer or a multi-layer laminate construction.

### Coating Composition

The patterned transparent conductors according to the present disclosure are prepared by coating a nanostructure-containing coating composition on a non-conductive substrate. To form a coating composition, the metal nanowires are typically dispersed in a volatile liquid to facilitate the coating process. It is understood that, as used herein, any non-corrosive volatile liquid in which the metal nanowires can form a stable dispersion can be used. Preferably, the metal nanowires are dispersed in water, an alcohol, a ketone, ethers, hydrocarbons or an aromatic solvent (benzene, toluene, xylene, etc.). More preferably, the liquid is volatile, having a boiling point of no more than 200° C., no more than 150° C., or no more than 100° C.

In addition, the metal nanowire dispersion may contain additives and binders to control viscosity, corrosion, adhesion, and nanowire dispersion. Examples of suitable additives and binders include, but are not limited to, carboxy methyl cellulose (CMC), 2-hydroxy ethyl cellulose (HEC), hydroxy propyl methyl cellulose (HPMC), methyl cellulose (MC), poly vinyl alcohol (PVA), tripropylene glycol (TPG), and xanthan gum (XG), and surfactants such as ethoxylates, alkoxylates, ethylene oxide and propylene oxide and their copolymers, sulfonates, sulfates, disulfonate salts, sulfosuccinates, phosphate esters, and fluorosurfactants (e.g., Zonyl® by DuPont).

In one example, a nanowire dispersion, or “ink” includes, by weight, from 0.0025% to 0.1% surfactant (e.g., a preferred range is from 0.0025% to 0.05% for Zonyl® FSO-100), from 0.02% to 4% viscosity modifier (e.g., a preferred range is 0.02% to 0.5% for HPMC), from 94.5% to 99.0% solvent and from 0.05% to 1.4% metal nanowires. Representative examples of suitable surfactants include Zonyl® FSN, Zonyl® FSO, Zonyl® FSH, Triton (×100, ×114, ×45), Dynol (604, 607), n-Dodecyl b-D-maltoside and Novek. Examples of suitable viscosity modifiers include hydroxypropyl methyl cellulose (HPMC), methyl cellulose, xanthan gum, polyvinyl alcohol, carboxy methyl cellulose, and hydroxy ethyl cellulose. Examples of suitable solvents include water and isopropanol.

The nanowire concentration in the dispersion can affect or determine parameters such as thickness, conductivity (including surface conductivity), optical transparency, and mechanical properties of the nanowire network layer. The percentage of the solvent can be adjusted to provide a desired concentration of the nanowires in the dispersion. In preferred embodiments the relative ratios of the other ingredients, however, can remain the same. In particular, the ratio of the surfactant to the viscosity modifier is preferably in the range of about 80 to about 0.01; the ratio of the viscosity modifier to the metal nanowires is preferably in the range of about 5 to about 0.000625; and the ratio of the metal nanowires to the surfactant is preferably in the range of about 560 to about 5. The ratios of components of the dispersion may be modified depending on the substrate and the method of application used. The preferred viscosity range for the nanowire dispersion is between about 1 and 100 cP.

Following the coating, the volatile liquid is removed by evaporation. The evaporation can be accelerated by heating (e.g., baking). The resulting nanowire network layer may require post-treatment to render it electrically conductive. This post-treatment can be a process step involving exposure to heat, plasma, corona discharge, UV-ozone, or pressure as described below.

Examples of suitable coating compositions are described in U.S. Published Application Nos. 2007/0074316, 2009/0283304, 2009/0223703, and 2012/0104374, all in the name of Cambrios Technologies Corporation, the assignee of the present disclosure.

The coating composition is coated on a substrate by, for example, sheet coating, web-coating, printing, and lamination, to provide a transparent conductor. Additional information for fabricating transparent conductors from conductive nanostructures is disclosed in, for example, U.S. Published Patent Application No. 2008/0143906, and 2007/0074316, in the name of Cambrios Technologies Corporation.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A double-sided transparent conductive film comprising:
a beam-blocking substrate having a first surface and a second surface opposite to the first surface;
a first conductive layer disposed on the first surface, the first conductive layer comprising a first plurality of conductive nanostructures;
a second conductive layer disposed on the second surface, the second conductive layer comprising a second plurality of conductive nanostructures, wherein the beam-blocking substrate is capable of blocking a laser beam having wavelengths in the range of 180 nm-1 mm.

2. The double-sided transparent conductive film of claim 1 wherein the beam-blocking substrate is capable of transmitting visible light (400-700 nm).

3. The double-sided transparent conductive film of claim 1 wherein the beam-blocking substrate comprises one or more beam-blocking agents.

4. The double-sided transparent conductive film of claim 1 wherein the beam-blocking substrate blocks IR light.

5. The double-sided transparent conductive film of claim 4 wherein the beam-blocking substrate is an IR-blocking layer comprising one or more IR dyes.

6. The double-sided transparent conductive film of claim 1 wherein the beam-blocking substrate comprises a UV-blocking layer.

7. The double-sided transparent conductive film of claim 6 wherein the UV-blocking layer comprises one or more UV-blocking agents comprises a chemical moiety selected from: salicylate, benzophenone, benzotriazole, thiazine, benzotriazine, and substituted acrylonitrile.

8. The double-sided transparent conductive film of claim 6, wherein the UV-blocking layer is a polyethylene terephthalate film comprising an UV-blocking agent.

9. The double-sided transparent conductive film of claim 1, wherein the conductive nanostructures are metal nanowires.

10. The double-sided transparent conductive film of claim 1 further comprising:
a first beam-blocking coating interposed between the first conductive layer and the beam-blocking substrate; and
a second beam-blocking coating interposed between the second conductive layer and the beam-blocking substrate.

11. The double-sided transparent conductive film of claim 10 wherein the first beam-blocking coating and/or the second beam-blocking coating comprises one or more beam-blocking agents.

12. A double-sided transparent conductive film comprises:
a first substrate;
a first conductive layer disposed on the first substrate, the first conductive layer comprising a first plurality of conductive nanostructures;
a second substrate;
a second conductive layer disposed on the second substrate, the second conductive layer comprising a second plurality of conductive nanostructures; and
a beam-blocking adhesive layer disposed between the first substrate and the second substrate, the beam-blocking adhesive layer and the first conductive layer being on opposite sides of the first substrate, and the beam-blocking adhesive layer and the second conductive layer being on opposite sides of the second substrate, wherein the beam-blocking adhesive layer is capable of blocking a laser beam having wavelengths in the range of 180 nm-1 mm.

13. The double-sided transparent conductive film of claims 12 wherein the beam-blocking adhesive layer blocks IR light (700 nm-1 mm).

14. The double-sided transparent conductive film of claim 13 13 wherein the beam-blocking adhesive layer is an IR-blocking layer comprising one or more IR dyes.

15. The double-sided transparent conductive film of claims 12 wherein the beam-blocking adhesive layer blocks UV light (180-400 nm).

16. The double-sided transparent conductive film of claim 15 wherein the beam-blocking adhesive layer comprises one or more UV-blocking agents comprises a chemical moiety selected from: salicylate, benzophenone, benzotriazole, thiazine, benzotriazine, and substituted acrylonitrile.

17. The double-sided transparent conductive film of claim 12 further comprising:
a first beam-blocking coating interposed between the first conductive layer and the first substrate; and
a second beam-blocking coating interposed between the second conductive layer and the second substrate.

18. The double-sided transparent conductive film of claim 17 wherein the first beam-blocking coating and the second beam-blocking coating are UV-blocking.

19. The double-sided transparent conductive film of claim 17 wherein the first beam-blocking coating and the second beam-blocking coating are IR-blocking.

20. The double-sided transparent conductive film of claim 12 wherein at least one of the first and the second substrate is IR-blocking or UV-blocking.

21. A method for double-sided patterning comprising:
providing a double-sided transparent conductive film of claim 1;
laser patterning the first conductive layer with a first laser beam; and
laser patterning the second conductive layer with a second laser beam, wherein laser patterning comprises directing the first laser beam to predetermined regions of the first conductive layer, and the second laser beam to predetermined regions of the second conductive layer, thereby independently creating insulating regions in the first and second conductive layers.

22. The method of claim 21 wherein laser patterning the first conductive layer and laser patterning the second conductive layer are carried out simultaneously.

23. The method of claim 21 wherein laser patterning the first conductive layer and laser patterning the second conductive layer are carried out serially.

24. The method of claim 21 wherein the beam-blocking substrate blocks 20-50% of the first laser beam energy or the second laser beam energy.
